(19) United States
(12) Patent Application Publication
(10) Pub. No.: US 2016/0225962 A1
(43) Pub. Date: Aug. 4, 2016

(54) NANOPARTICLE GRADIENT REFRACTIVE INDEX ENCAPSULANTS FOR SEMI-CONDUCTOR DIODES

(71) Applicant: Empire Technology Development LLC, Wilmington, DE (US)

(72) Inventors: Michael Keoni Manion, Seattle, WA (US); Benjamin William Millar, Rosebery (AU); George Charles Peppou, Hornsby Heights (AU)

(21) Appl. No.: 14/610,304

(22) Filed: Jan. 30, 2015

(51) Int. Cl. H01L 33/50; H01L 33/00; H01L 33/56

(52) U.S. Cl. CPC H01L 33/504; H01L 33/56; H01L 33/005; H01L 2933/0033; H01L 2933/005; H01L 2933/0041

(57) ABSTRACT

A gradient refractive index light emitting diode is disclosed. The light emitting diode includes a die at least partially encapsulated within a polymer, and nanoparticles dispersed within the polymer along a concentration gradient related to the distance from the die. The refractive index of the nanoparticles is different from the refractive index of the polymer.

### BACKGROUND

Unless otherwise indicated herein, the materials described in this section are not prior art to the claims in this application and are not admitted to be prior art by inclusion in this section.

A major cause of loss of light extraction efficiency from light emitting diodes (LEDs) is the internal reflection of produced light from barriers between semiconductor and encapsulant, and encapsulant and lens. A method of reducing the refractive index discrepancies between each of the components will decrease the range of incident angles over which total internal reflection will occur, while also reducing partial reflection.

Production LEDs are increasingly employing high power semiconductors, such as gallium nitride (GaN), that emit in the short visible to UV wavelength range. At these wavelengths the refractive index of GaN climbs rapidly, and greatly outstrips the refractive index increase at such wavelengths of polymers used as encapsulants. The problem of refractive index mismatch between diode and encapsulant thus causes an even greater reduction in efficiency than in longer wavelength emitters.

### SUMMARY

In one embodiment, a gradient refractive index (GRIN) light emitting diode (LED) is disclosed. The LED includes a die at least partially encapsulated within a polymer. Nanoparticles are dispersed within the polymer along a concentration gradient related to their distance from the die. The nanoparticles have a refractive index that is different from the refractive index of the polymer.

In another embodiment, a method for making a GRIN LED is disclosed. The method includes: doping a polymer with charged nanoparticles that have a refractive index that is different from the refractive index of the polymer; at least partially encapsulating a die in the doped polymer; and applying a voltage to the die that causes the charged nanoparticles to migrate, thereby dispersing the nanoparticles along a concentration gradient related to their distance from the die.

In another embodiment, a method of making a GRIN LED is disclosed. The method includes: doping a polymer with charged droplets, wherein the droplets comprise gas, plasma or liquid, and have a droplet refractive index that is different from the refractive index of the polymer; at least partially encapsulating a die in the doped polymer; and applying a voltage to the die that causes the charged droplets to migrate, thereby dispersing the droplets along a concentration gradient related to their distance from the die.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through use of the accompanying drawings.

FIGS. 1A and 1B show the progression from uncured to cured encapsulant. The encapsulant illustrated in FIG. 1A is uncured and unaltered and has an even distribution of nanoparticles. The encapsulant illustrated in FIG. 1B has been altered by charge attraction and cured.

FIG. 2 is a graph comparing the effects of nanoparticle concentration (TiO₂ volume fraction) on the bulk refractive index of the doped encapsulant (epoxy).

FIG. 3 illustrates formation of a gradient refractive index encapsulant, as the diode is run in reverse voltage causing migration of positively charged nanoparticles to the surface of the negatively charged die surface.

FIG. 4 shows phosphor particles dispersed together with nanoparticles along a gradient within the encapsulant.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

### Gradient Refractive Index (GRIN) Light Emitting Diodes (LEDs)

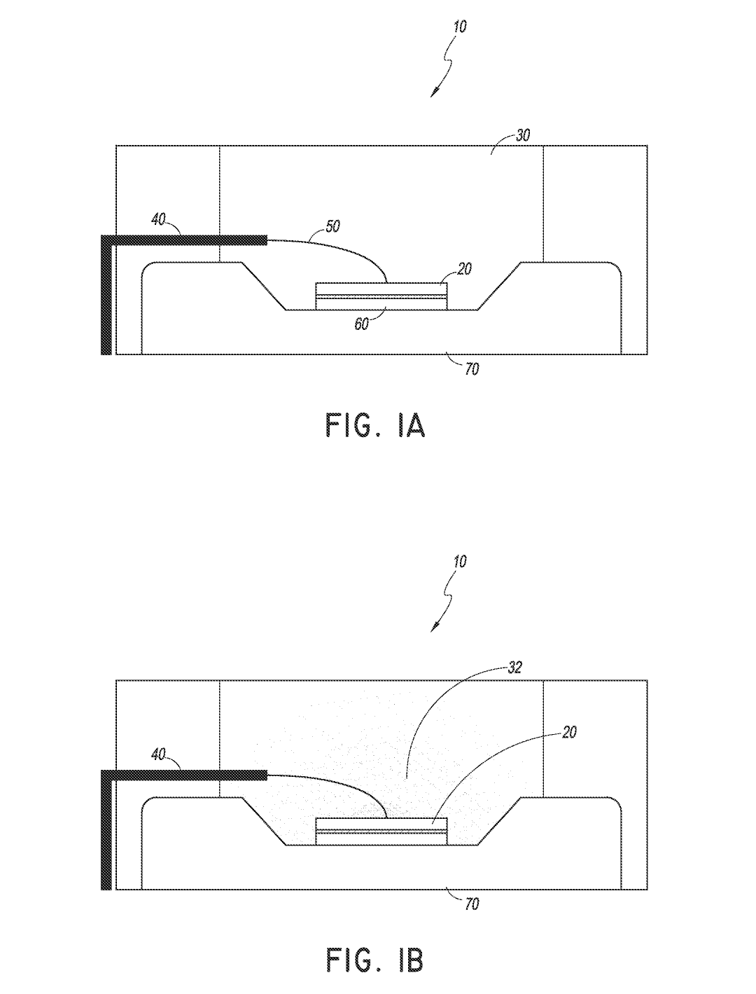

In some embodiments, materials and methods are disclosed for manufacturing a GRIN LED in which a refractive index gradient is formed during encapsulant curing via electrophoresis of suspended charged nanoparticles powered by the charge on the LED die itself. Charged nanoparticles are distributed evenly within the uncured encapsulant media and allowed to migrate towards the diode as dictated by electrostatic attraction. This process may be carried out in situ during manufacture, as illustrated in FIGS. 1A and 1B. With reference to FIG. 1A, a diode 10 is illustrated. The diode 10 includes an LED die 20 surrounded by an uncured encapsulant 30. The distribution of nanoparticles in the encapsulant is even. The die 20 is connected to the anode 40 by wire 50. The LED die includes a cathode (n-type) side of the diode junction 60 and an anode (p-type) side of the diode junction 22. Together the cathode 60 and anode 22 sides of the diode junction form the LED die 20. The die is typically immobilized on a highly conductive solder or epoxy (not shown in the figures), which is in contact with the cathode 70. The migration process may be slowed and halted by the controllable curing of the encapsulant media (e.g., a polymer). In one embodiment, nanoparticles form a gradient that corresponds to the charge profile of the diode, which is related to its light emission. Accordingly, each encapsulant may be tailored for its particular die. The degree of total internal reflection may be drastically reduced by the presence of a continuous gradient rather than a series of abrupt refractive index steps. This same technique has potential to increase efficiency and reduce power consumption for optical emitters and detectors in optoelectronic applications.

In one embodiment, the encapsulant cover could be produced separately and placed once cured, however, this may reduce the primary benefits of the above-proposed method. The in situ formation advantageously allows for perfect adhesion to the LED die without air-gaps, filler or adhesive interrupting the refractive index gradient. The formation of the gradient in situ by the LED itself allows each encapsulant piece to be tuned to the emission of its die, improving efficiency.

As illustrated in FIG. 1B, the distribution of nanoparticles in the uncured encapsulant (from FIG. 1A) has been altered by charge attraction to produce a concentration gradient within the encapsulant 30. In the illustrated embodiment, the concentration of nanoparticles increases progressively toward the LED die 20. Migration of the nanoparticles toward the LED die slows and may be halted by curing of the encapsulant media. Similarly, modulation of the voltage across the die can be used to initiate, slow and/or stop migration of charged nanoparticles, simultaneously with curing, and/or independently from curing.

More particularly, electrophoresis of charged nanoparticles may comprise the following example. The voltage is applied across the LED die between the cathode base and the anode bond wire. The voltage is applied in reverse (e.g. to reverse bias the LED junction), thus there is no conduction across the LED junction, and charge builds up accordingly at the surface adjacent the nanoparticle filled encapsulant. The voltage applied in this direction cannot exceed the breakdown voltage of the junction, which depends on the device configuration but may be typically on the order of 5V. In some examples, the voltage may be applied between the top electrode wire and an externally applied electrode on top of the encapsulant. The external electrode may be charged the same as the nanoparticles (thus electrostatically repelling the nanoparticles), and may be shaped to the external shape of the encapsulant. This may eliminate concerns with the die breakdown voltage, but may require a temporary circuit and extra electrode, while removing the die specific gradient shape.

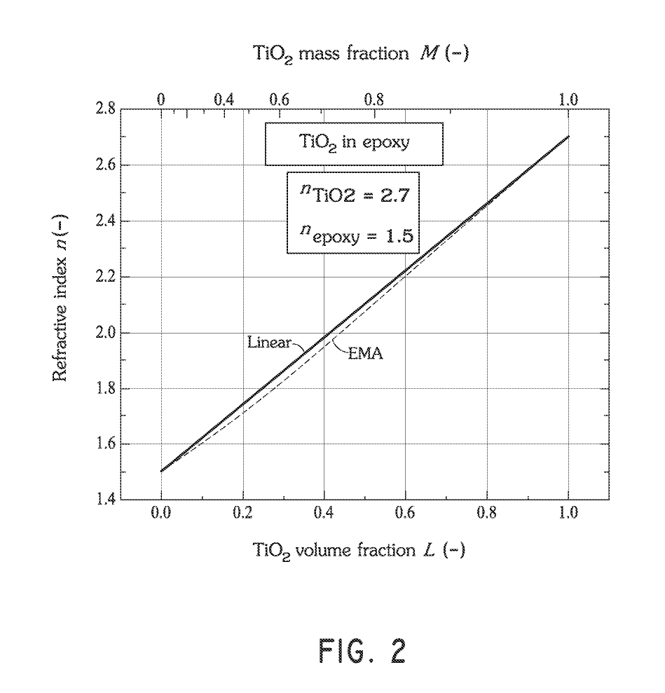

GRIN controlled nanoparticle doped polymers can be used to eliminate discrete boundaries between components, significantly reducing the proportion of light that is internally reflected, thus improving light extraction efficiency. Doping of polymers with nanoparticles allows achievement of very high refractive indices in the bulk material. The refractive index of the bulk material may vary in relation to the mass fraction and the intrinsic refractive index of dispersed nanoparticles. Higher intrinsic refractive index of the dispersed nanoparticles and/or higher concentrations tend to raise the refractive index of the bulk material, whereas lower intrinsic refractive index of the dispersed nanoparticles and/or lower concentrations tend to reduce the refractive index of the bulk material. As illustrated in FIG. 2, in TiO₂-doped epoxy, a linear relationship was observed between the concentration of nanoparticles (TiO₂ volume fraction) and the refractive index of the bulk material (epoxy).

The nanoparticle materials used to modify the refractive index of the encapsulant may include for example, oxides, dielectric oxides, dielectric particles, semiconductor particles, phosphides, nitrides, carbides, ceramic particles, metalloids etc.

In one embodiment, an uncured polymer resin is uniformly doped with nanoparticles of higher refractive index relative to the encapsulant, and of size sufficiently small relative to the application LED emission wavelength that they are non-scattering. Particle size on the order of 10-50 nm are desired in order to avoid scattering. Average and maximum particle diameters of less than about ¼ of the emitted wavelength are acceptable, but for some operations (where minimum scattering and absorption are sought), particle diameters of about 5 nm to about 10 nm. Alternatively, to minimize cost, larger diameter particles, e.g., about 10 nm to about 25 nm may be used. As other factors are more easily controlled during the process, particle shape may be optimized for ease of percolation through the encapsulant polymer. Therefore in some embodiments, regular, spherical shape may be the most appropriate.

Several nanoparticle materials with high refractive index that are ideal for GRIN formation in polymers are easily charged. Two exemplary candidates are titania (TiO₂) and zirconia (ZrO₂). Both may be easily charged positive or negative, and may be used as nanoparticle materials to dope polymers for optical property modification. Methods for charging particles (such as nanoparticles) include: charging by application of charged gas to particles suspended in droplet form (then dried), charging by corona discharge whilst suspended in droplet form (then dried), atomized in liquid form by a corona discharge, blown in particulate form across a charged plate, or through charged mesh. The surfaces of particles may be complexed or otherwise coated with ionic compounds or more easily charged compounds, such as molecular compounds having an ionization potential such that the compounds are ionizable by a reasonable voltage, such as 10 V or less. Charged particles may be used to produce sufficient attractive/repulsive force to cause gradient formation in the presence of an applied field at a feasible rate for manufacturing, whilst overcoming internal viscosity of the polymer. In some examples, sufficient force is required to allow gradient formation to occur during a limited curing time. In some embodiments, electrophoresis of high permittivity particles in a low permittivity media may produce a permittivity (e.g. refractive index) gradient. However,such an approach may lead to a lower achievable velocity, and the viscosity of the curing encapsulant may be reduced (e.g. by reformulation, addition of other components, heating, and the like) to allow gradient formation to be completed before curing is completed. In some examples, particles, such as nanoparticles, may comprise dielectric particles, such as ceramic dielectric particles. In some examples, particles may comprise an oxide (such as a metal oxide or a semi-metal oxide), a nitride (such as a metal nitride or a semi-metal nitride), a carbide (such as a metal carbide or a semi-metal carbide, a phosphide, and the like. TABLE 1 includes a list of nanoparticle materials with intrinsic refractive indices that tend to be higher than typical encapsulant polymers. In some examples, titania and/or zirconia particles are used in the modification of polymeric refractive indices in LED lenses. These ceramic materials are also capable of holding either positive or negative static charges, and can be formed into gradients by electrophoresis.

TABLE 1
Nanoparticle materials with refractive
index higher than encapsulant polymers

| | Relevant | | |
|---|---|---|---|
| | Refractive index | Transmission range | |
| Material | (within 300-550 nm) | (Wavelength) | |
| Titania (TiO₂) | 2.5-2.6 | | |
| Zirconia (ZrO₂) | 2.15-2.18 | 340-12000 | nm |
| Tellurium dioxide (TeO₂) | 2.4 | 350-6500 | nm |
| Silicon carbide (SiC) | 2.55 | | |
| Diamond | 2.45 | | |
| Niobia (Nb₂O₅) | ~2.33 | 320-8000 | nm |
| Hafnium dioxide (HfO₂) | 1.95 | 220-12000 | nm |
| Yttrium oxide (Y₂O₃) | ~1.8 | | |
| Tantalum oxide (Ta₂O₅) | ~2.16 | 300-10000 | nm |
| Antimony trioxide (Sb₂O₃) | ~2.35 | | |
| Gallium phosphide | 3.45 at 550 nm | 500-800 | nm |
| Gallium nitride (GaN) | 2.7 | ≦400 | nm |
| Alumina (Al₂O₃) | ~1.65 (very similar | | |
| | to the bulk polymer | | |
| | itself - limited use) | | |
| Germanium dioxide (GeO₂) | ~1.65 (very similar | | |
| | to the bulk polymer | | |
| | itself - limited use) | | |

In some examples, the particles are charged with a charge polarity that causes the particles to be attracted towards the LED die when it is run at a reverse voltage, due to the buildup of charge on its external surface. A wide range of methods exist for charging and dispersing of nanoparticles into a polymer resin in a homogeneous manner. These methods include surface coatings and modifications to allow both suspension and convey particle charge.

Current may be limited to prevent damage to the diode. In some embodiments of a method for forming a GRIN LED, a maximum reverse voltage before dielectric breakdown of the LED semiconductor junction, may be in a range of about 0.5V to about 10V. In some embodiments, the maximum reverse voltage is typically on the order of 5V. These examples are not limiting.

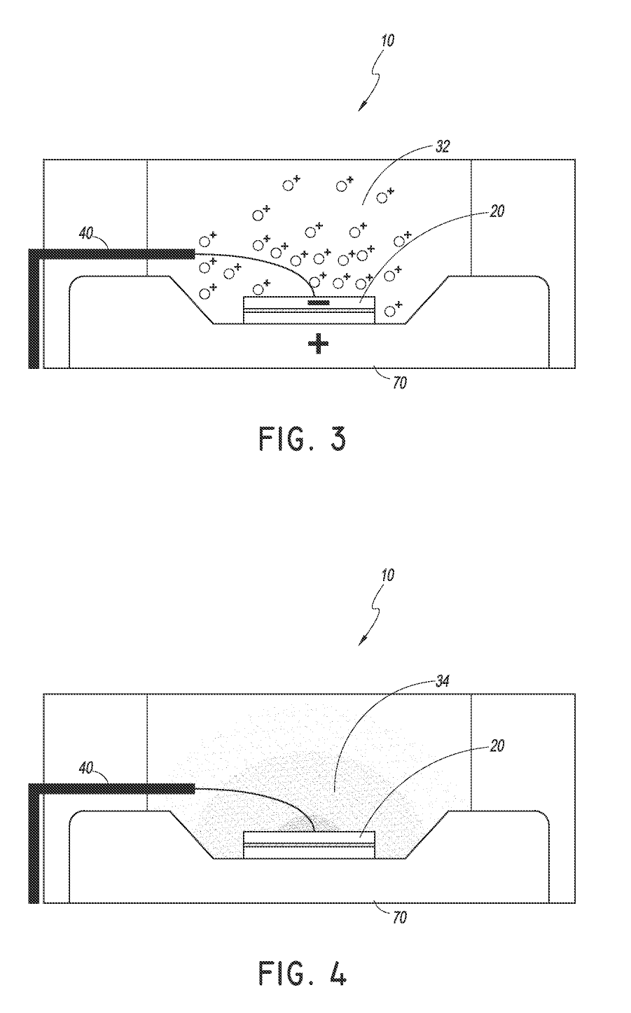

The LED die may be encapsulated in a moderate viscosity uncured doped polymer resin and run at reverse voltage prior to and/or during curing. Charge builds up on the LED surface and electrostatic attraction causes oppositely charged nanoparticles to migrate. In the embodiment illustrated in FIG. 3, as the diode 10 is run in reverse, positively charged nanoparticles 80 (not drawn to scale) migrate through the uncured encapsulant 30 towards the negative charge buildup on the surface of the LED die 20. As the positively charged nanoparticles migrate towards the negatively charged die, vacated polymer regions are filled with particles from farther from the diode until the extremities are exhausted. This electrophoresis results in a high concentration of particles close to the die, with particle concentration decreasing as a function of distance from the charged surface of the die, thereby forming the refractive index gradient.

In other embodiments, nanoparticles with a lower refractive index than the encapsulant may be given the same charge as the die surface, such that the particles migrate away from the die due to charge repulsion during the electrophoretic curing process. The result is a GRIN LED, where the refractive index of the encapsulant decreases with distance from the LED die. Some nanoparticle materials which have lower relative refractive indices are set forth in TABLE 2 (below).

TABLE 2
Nanoparticle materials with refractive
index lower than encapsulant polymers

| | Relevant Refractive index | Transmission range |
|---|---|---|
| Material | (within 300-550 nm) | (Wavelength) |
| Silica (SiO₂) | ~1.55 | |
| Gallium oxide (TeO₂) | 1.45 | |

In some embodiments, a suspension of negatively charged droplets of a low refractive index gas (plasma) or liquid could potentially be influenced in a similar way to form an electrophoretically controlled porosity gradient giving an even greater reduction in refractive index toward the extremities of the encapsulant.

Charged gas/plasma may be (He, Ne, Ar, and the like), nitrogen, or mixtures may be used. The gas is ionized using an arc. The uncured resin is aerated in bulk with this gas/plasma, using rapid stirring and/or atomized injection. The resulting droplets contained are sufficiently small that buoyancy does not overcome viscosity, similarly to the effect that contains solid particles. This aerated resin is deposited. Any liquid that is of a significantly different RI to the cured encapsulant resin that is immiscible with the uncured resin may be used. The liquid is atomized by an arc, and may be further chared by plasma, before being injected into bulk uncured encapsulant, and stirred into a suspension.

The gas or liquid droplets are formed into a gradient in the same manner as the solid nanoparticles, using a charge on the surface of the die. Liquids used may be uncurable hydrocarbon oils, silicone oils or fluorinated oils, all with refractive indexes around 1.3. These may be charged and atomized by a corona discharge, and dispersed into an encapsulant resin in which they are immiscible.

In some embodiments, LEDs that do not utilize extensive phosphors may be configured to employ charged nanoparticles of the same material as used in the light-emitting diode, or semiconductors with similar emission and transmission bands. Such materials may interfere with phosphor produced light as it is shifted to an area of the spectrum that may be absorbed by the material. This only applies to semiconductor dispersions, as they possess narrow transmission bands compared to ceramic oxides. If at least two options for an emission band exist, one preferred implementation would be to use the lower refractive index semiconductor as the LED, and the higher refractive index material as the nanoparticle dopant.

### Phosphor Particles

In some embodiments, phosphor particles are included, for example dispersed within the polymer, and in some embodiments the phosphor particles may have a phosphor particle concentration that has a concentration gradient related to a distance from the die. Phosphor particles may be charged in the same manner and subjected to the same gradient accumulation around the LED die as the nanoparticles as illustrated in FIG. 4. In other embodiments that include phosphor particles, the phosphor particles may be left uncharged and thus remain evenly distributed throughout the encapsulant. Some example phosphor particles include doped or undoped Yttrium Aluminium Garnet (YAG), doped zinc sulfide, doped SiAlON, doped BaMgₓAlₓOₓ (BAM). These may be doped with copper or rare earth elements such as europium or cerium.

The nanoparticle refractive index gradient may also operate as a focusing lens for scattered light produced from dispersed phosphor, thereby further eliminating components. The focusing function may be equivalent to that of a normal GRIN lens. The gradient will tend to not perform significant function as a focusing lens for light directly emitted from the diode, as it is formed perpendicular to the emitted light's path.

### Encapsulant Polymer

In some embodiments, the encapsulant may be any material that can be doped with nanoparticles in a liquid, semi-liquid, and/or low viscosity state that allows migration of charged nanoparticles when an electric potential is applied to the die, and which material can subsequently be induced, polymerized or cured into a solid, semi-solid and/or high viscosity state that prevents further migration of the nanoparticles, which have formed a concentration gradient. In some embodiments, the encapsulant is a polymer. The polymer may be selected from any polymers commonly used in LED manufacture to encapsulate the die. In some embodiments, stable encapsulant polymers, such as silicone resins and epoxies, possess sufficient resistivity to prevent short term charge leakage and allow electrophoresis of charged nanoparticles. Examples of encapsulant polymers that possess sufficient resistivity to prevent charge leakage from the nanoparticles for the time required for processing, and that may be used to form GRIN LEDs include polyurethane resins, PVDF, PTFE and copolymers of other fluoropolymers.

In one embodiment, base polymers with good resistance to high intensity radiation may be used, such as fluorinated polymers, whereas these base polymers may not have a sufficiently high refractive index unmodified (by doping with high refractive index nanoparticles) to eliminate reflection at the crystal/encapsulant boundary. Advantageously, the use of a gradient refractive index may eliminate the discrete outer boundary between lens and encapsulant. Silicone resins, epoxies, and similar stable encapsulant polymers typically possess sufficient resistivity to prevent short term charge leakage and allow electrophoresis of charged nanoparticles.

### Encapsulant Curing

The curing process for the disclosed encapsulant materials may be similar to that employed currently for known LED encapsulants. Curing of the polymer encapsulant may involve the addition of a chemical initiator or polymerization component for rapid or delayed curing (typically epoxy), exposure to UV or other wavelengths for a varied period of time for photopolymerization or crosslinking curing (typically polyurethane or fluoropolymer), the application of a critical temperature for initiation or rate control of curing or crosslinking (typically silicone). Chemical initiators may be low volume fractions or contain significant polymer components. Curing time may be closely controlled for short or long periods depending on time for gradient formation. Each method of polymerization and crosslinking including chemical (eg mixing), UV photopolymerisation and thermal initiation for techniques are available for epoxies, polyurethane, silicones and fluoropolymers. Certain compositions from each of these groups may be cured by each of the above methods. The rate at which these processes proceed is also highly variable and easily controlled. The period of gradient formation may be completed at any stage, prior to complete setting of the resin.

### Advantages of Disclosed Embodiments

Some advantages that may be realized through one or more of the disclosed embodiments include:

Simple alteration of existing manufacturing to provide high extraction efficiency and eliminate the loss of light brought about by the multiple dedicated stages of existing designs.

No major change in fundamental materials or production line. Particles may be suspended and distributed throughout encapsulant material. Electrophoresis may be carried out during curing.

Use of charged nanoparticle response to charge on the LED die itself to generate particle gradient.

Automatic unique tailor made GRIN shape may be formed by the disclosed methods. The gradient index profile, for example in two or more dimensions, may be configured to reduce reflection losses from solid-sold interfaces and/or solid-air surfaces, focus emitted light, provide arbitrary beam shaping, or some combination thereof

The gradient may be formed in a manner that does not affect encapsulant shape or phosphor doping, as it may be generated entirely by selective motile forces on the nanoparticles.

GRIN methods disclosed may avoid problems associated layering methods, in which discrete layers must be less than the mean optical scattering length to reduce Fresnel reflection—thereby requiring tight manufacturing tolerance requirements and separate sophisticated manufacturing processes.

### Variations and Combinations of the Disclosed Embodiments

Various features of gradient refractive index LEDs are disclosed herein. In some embodiments, the LEDs may include the following features and combinations of features:

In a first embodiment, a gradient refractive index (GRIN) light emitting diode (LED) is disclosed. The LED includes a die at least partially encapsulated within a polymer, and nanoparticles dispersed within the polymer along a concentration gradient related to the distance from the die. The refractive index of the nanoparticles is different from the refractive index of the polymer.

In a variation of the above described LED, the nanoparticle concentration may decrease with increasing distance from the die.

In a further variation to any of the herein-described LEDs, the nanoparticle refractive index may be greater than the polymer refractive index. For example, the nanoparticles may include titania, zirconia, tellurium dioxide, silicon carbide, diamond, niobia, hafnium dioxide, yttrium oxide, tantalum oxide, antimony trioxide, gallium phosphide, gallium nitride, alumina, germanium dioxide, or a combination thereof

In another variation of the above described LED, the nanoparticle refractive index may be less than the polymer refractive index. For example, the nanoparticles may include silica, gallium oxide, or a combination thereof

In further variations to any of the herein-described LEDs, the average diameter of the nanoparticles may be at least about 5 nm, less than or equal to about 100 nm, and/or between about 10 nm and about 50 nm.

In a further variation to any of the herein-described LEDs, the nanoparticles and the die may include the same material.

In further variations to any of the herein-described LEDs, the transmission band of the nanoparticles may include a range of wavelengths that encompasses at least a majority of wavelengths in an emission band of the die, and/or substantially all of wavelengths in an emission band of the die.

In a further variation to any of the herein-described LEDs, the polymer may also include phosphor particles dispersed within the polymer. In some embodiments, the phosphor particles may be uniformly distributed throughout the polymer. In other embodiments, the phosphor particles may be dispersed along a concentration gradient related to a distance from the die. The concentration of phosphor particles may decrease with increasing distance from the die, or increase with increasing distance from the die.

In a further variation to any of the herein-described LEDs, the polymer may also include a porosity gradient having droplets dispersed within the polymer along a concentration gradient related to the distance from the die. The concentration of droplets may decrease with increasing distance from the die, or increase with increasing distance from the die. In such variations that include a porosity gradient, the droplets may include gas, plasma, or liquid.

In a second embodiment, a method of making a light emitting diode (LED) is disclosed. The method may include: doping a polymer with nanoparticles, in which the nanoparticles have a nanoparticle refractive index, and the nanoparticles have an electric charge; at least partially encapsulating a die in the polymer; and applying a voltage to the die, such that the nanoparticles migrate, thereby dispersing the nanoparticles along a concentration gradient related to a distance from the die.

In variations of the above described method, the nanoparticles disperse along a concentration gradient that decreases with increasing distance from the die, or increases with increasing distance from the die.

In further variations to any of the herein-described methods, the refractive index of the nanoparticles may be greater than a refractive index of the polymer, or less than a refractive index of the polymer. Examples of nanoparticles that tend to be greater than the refractive indices of encapsulate polymers include titania, zirconia, tellurium dioxide, silicon carbide, diamond, niobia, hafnium dioxide, yttrium oxide, tantalum oxide, antimony trioxide, gallium phosphide, gallium nitride, alumina, germanium dioxide, or a combination thereof. Examples of nanoparticles that tend to be less than the refractive indices of encapsulate polymers include silica, gallium oxide, or a combination thereof

In a further variation to any of the herein-described methods, the step of applying the voltage causes the nanoparticles to migrate toward the die or away from the die depending on the electric charge of the nanoparticles. In one embodiment, the voltage is no more than about 5 volts.

In further variations to any of the herein-described methods, the average diameter of the nanoparticles may be at least about 5 nm, less than or equal to about 100 nm, and/or between about 10 nm and about 50 nm.

In further variations to any of the herein-described methods, the transmission band of the nanoparticles may include a range of wavelengths that encompasses at least a majority of wavelengths in an emission band of the die, and/or substantially all of wavelengths in an emission band of the die.

In a further variation to any of the herein-described methods, the nanoparticles and the die may include the same material.

In another variation to any of the herein-described methods, a step of dispersing phosphor particles within the polymer may be added. In some embodiments, the step of applying a voltage causes the phosphor particles to disperse along a concentration gradient related to a distance from the die. The concentration of phosphor particles may decrease with increasing distance from the die, or increase with increasing distance from the die, or where the phosphor particles are electrically neutral (carry no electric charge), they may remain uniformly distributed throughout the polymer.

In a further variation to any of the herein-described methods, the polymer may be an uncured resin, and the method may include a step of curing the uncured resin before, during or after application of the voltage to the die. In one embodiment, the voltage may be applied at the same time as curing the uncured doped resin. Curing may commence prior to the application of voltage, but should not generally be complete before voltage is applied. Voltage may be applied prior to any curing step (for resin compositions where this is possible) as suspended nanoparticles will not drift without external force due to viscosity. Voltage may be applied during curing if curing and gradient formation times are able to be matched.

In a further variation to any of the herein-described methods, the method may also include controlling the migration rate of the nanoparticles by controlling the viscosity of the polymer, controlling the value of the applied voltage, controlling the value of the charge on the charged nanoparticles, controlling the curing rate of the uncured polymer, or a combination thereof.

In a further variation to any of the herein-described methods, the method may also include controlling a refractive index distribution of the nanoparticles dispersed along the concentration gradient by controlling a quantity of the charged nanoparticles used to dope the polymer, controlling a refractive index of the charged nanoparticles, or a combination thereof

In a further variation to any of the herein-described methods, the method may also include doping the polymer with droplets having an electric charge.

In another embodiment, a method of making a light emitting diode (LED) is disclosed. The method includes: doping a polymer with droplets, in which the droplets have a droplet refractive index, and the droplets have an electric charge; at least partially encapsulating a die in the polymer; and applying a voltage to the die, such that the droplets migrate, thereby dispersing the droplets along a concentration gradient related to a distance from the die. The concentration of droplets may decrease with increasing distance from the die, or increase with increasing distance from the die. The droplets may include gas, plasma, or liquid.

In another embodiment, a gradient refractive index (GRIN) semiconductor diode is disclosed. The GRIN semiconductor diode includes a die at least partially encapsulated within a polymer, in which nanoparticles with a nanoparticle refractive index are dispersed within the polymer with a concentration gradient related to a distance from the die. The die may be a light emitting diode die or a photodetector diode die.

In another embodiment, a method of making a semiconductor diode is disclosed. The method includes: doping a polymer with charged nanoparticles including a selected refractive index; at least partially encapsulating a die in the doped polymer; and applying a voltage to the die such that the nanoparticles migrate, thereby dispersing the nanoparticles along a concentration gradient related to a distance from the die. The die may be a light emitting diode die or a photodetector diode die.

### EXAMPLES

Additional embodiments are disclosed in further detail in the following examples, which are not in any way intended to limit the scope of the claims.

### Example 1

### Method of Making a GRIN LED Using High Refractive Index Nanoparticles

Roughly spherical, positively charged Titanium dioxide (TiO₂, RI:2.45) particles of an average diameter of 10 nm are dispersed into suspension by stirring into uninitiated epoxy resin (cured RI: 1.5). The added particles compose 25% volume fraction of the resin/particle mix. A slow cure chemical polymerization initiator (˜1 hr for curing) is added to the resin and homogenized by stirring. The particle doped resin is then immediately applied as encapsulant to each LED die in an array. A reverse voltage of 5V is applied to each diode for 1 hr until curing is completed. The particles are drawn towards the diode during this time, resulting in a gradient of high to low refractive index from the die outwards.

### Example 2

### Method of Making a GRIN LED Using Low Refractive Index Nanoparticles

Roughly spherical, negatively charged Gallium Oxide (Ga₂O₃, RI:1.45) particles of an average diameter of 25 nm are dispersed into suspension by stirring in a photopolymerizable polyurethane (cured RI: 1.58). The added particles compose 10% volume fraction of the resin/particle mix. The particle doped resin is applied as encapsulant to each LED die in an array. A reverse voltage of 3V is applied to each diode for 30 minutes. The low RI particles are repelled from the diode during this time, resulting in a gradient of high to low refractive index from the die outwards. Following this, each LED is irradiated with UV light for 30 seconds to polymerize the resin, preserving this gradient.

### Example 3

### Method of Making a GRIN LED Using Phosphor Particles

Roughly spherical, positively charged Zirconium dioxide (ZrO₂, RI:2.1) particles of an average diameter of 10 nm are dispersed into suspension by stirring into a photopolymerisable PVDF-PTFE copolymer (cured RI: 1.41). The added particles compose 10% volume fraction of the resin/particle mix. Additional 100 nm diameter uncharged phosphor particles (Europium doped Yttrium Aluminium Garnet [Eu:YAG]) are added to the uncured resin mix at a volume fraction of 10%. The Refractive index and phosphor particle doped resin is applied as encapsulant to each LED die in an array. A reverse voltage of 5V is applied to each diode for 10 minutes. The charged high RI particles are attracted to the diode during this time, resulting in a gradient of high refractive index to low from the die outwards. The Phosphor particles remain evenly dispersed. Following this, each LED is irradiated with UV light for 5 seconds to polymerise the resin, preserving this gradient.

### Example 4

### Method of Making a GRIN LED with a Porosity Gradient

Negatively charged Helium plasma (RI: 1) is injected and dispersed to a droplet diameter of 20 nm into a chemically cured silicone resin (cured RI: 1.45). The added plasma composes 5% volume fraction of the resin/particle mix. A slow cure chemical polymerization initiator (˜30 minutes for curing) is added to the resin and homogenized by stirring. The plasma doped resin is applied as encapsulant to each LED die in an array. A reverse voltage of 5V is applied to each diode for 10 minutes. The low RI droplets are repelled from the diode during this time, resulting in a gradient of high refractive index to low from the die outwards, and curing preserves this gradient.

In some examples, a gradient refractive index (GRIN) light emitting diode (LED) comprises: a die at least partially encapsulated within a polymer; and nanoparticles dispersed within the polymer, wherein the nanoparticles have a nanoparticle concentration having a concentration gradient related to a distance from the die, and the nanoparticles have a nanoparticle refractive index, the polymer has a polymer refractive index, and the nanoparticle refractive index is different from the polymer refractive index. In some examples, the nanoparticle concentration may decrease or increase with increasing distance from the die. In some examples, the nanoparticle refractive index may be greater than, or in some examples less than, the polymer refractive index.

In some embodiments, the nanoparticles may comprise dielectric nanoparticles. In some examples, the nanoparticles may comprise oxide nanoparticles, such as metal oxide nanoparticles. In some examples, nanoparticles may comprise nitride nanoparticles, such as metal nitride nanoparticles, silicon nitride nanoparticles, and the like. In some examples, nanoparticles may comprise carbide nanoparticles, such as metal carbide nanoparticles . In some examples, nanoparticles may comprise titania, zirconia, tellurium dioxide, silicon carbide, diamond, niobia, hafnium dioxide, yttrium oxide, tantalum oxide, antimony trioxide, gallium phosphide, gallium nitride, alumina, germanium dioxide, or a combination thereof. In some embodiments, the nanoparticles may comprise silica, gallium oxide, or a combination thereof

In some embodiments, the nanoparticles have an average diameter of at least about 5 nm, or an average diameter of less than or equal to about 100 nm, or an average diameter of between about 10 nm and about 50 nm. In some embodiments, the nanoparticles and the die may comprise the same material, such as a dielectric material or a semiconductor material. In some embodiments, nanoparticles may be substantially spherical. In some embodiment, nanoparticles may be disk-shaped, rod-like or otherwise shaped, or have a combination of shapes. In some embodiments, the nanoparticles may have dimensions substantially less than that of the light color emitted by the LED, so that the polymer-nanoparticle composite has an effective refractive index that may be estimated by effective medium theory. In some embodiments, a 3D printer may be used to print a polymer composite, for example by printing a combination of organic monomers (or similar) and dielectric nanoparticles. In some examples, dielectric nanoparticles may have a coating, for example a molecular coating to improve dispersion or solution in the polymer, to introduce charged moieties, and the like. An electric field may be further used to achieve a desired nanoparticle concentration profile after printing.

In some embodiments, a transmission band of the nanoparticles comprises a range of wavelengths that encompasses at least a majority of wavelengths in an emission band of the die. In some embodiments, nanoparticles may have a diameter appreciably less than a wavelength of light emitted by the LED. In some embodiments, a transmission band of the nanoparticles comprises a range of wavelengths that encompasses substantially all of wavelengths in an emission band of the die.

In some embodiments, the polymer may further comprise a luminophor, such as luminophor particles, such as a fluorophor particles or phosphor particles dispersed within the polymer. In some embodiments, the term phosphor particle may be used to describe any such luminophor particle. Phosphor particles may be dispersed along a concentration gradient related to a distance from the die. The concentration of phosphor particles may decrease with increasing distance from the die.

In some embodiments, the polymer may further comprises a porosity gradient comprising droplets dispersed within the polymer along a concentration gradient related to a distance from the die. The concentration of droplets may vary (e.g. decrease) with increasing distance from the die. In some examples, the droplets may comprise gas (such as air, nitrogen, rare gas, and the like), plasma or liquid.

In some embodiments, a method of making a light emitting diode (LED) comprises: doping a polymer with nanoparticles where the nanoparticles have a nanoparticle refractive index, and the nanoparticles may have an electric charge; at least partially encapsulating a die in the polymer; and applying a voltage to the die, such that the nanoparticles migrate, thereby dispersing the nanoparticles along a concentration gradient related to a distance from the die. In some examples, the nanoparticles disperse along a concentration gradient that decreases with increasing distance from the die. Applying the voltage may the nanoparticles to migrate toward the die, or migrate away from the die, for example as a function of the applied electrical field, and permittivity of the nanoparticles. For example, relatively higher permittivity nanoparticles may tend of accumulate in relatively high field electric field regions. In some examples, nanoparticles may be imbued with an electrical chage. The refractive index of the nanoparticles may greater than a refractive index of the polymer, for example at an operational wavelength of the LED. The applied voltage may be no more than about 5 volts, for example applied between the die and another region of the LED. In some embodiments, other particles such as microparticles may be used, for example in IR LEDs. In some embodiments, an example method may comprise adding phosphor particles to the polymer. Applying the voltage may cause the particles (e.g. phosphor particles and/or nanoparticles) to migrate, thereby dispersing the phosphor particles along a concentration gradient related to a distance from the die. Phosphor particles may disperse along a concentration gradient that decreases with increasing distance from the die.

In some examples, a polymer may be substantially or at least partially uncured during the nanoparticle migration, and the method further may further comprise curing the polymer before, during or after application of the voltage to the die. In this context, an uncured polymer may be associated with a polymerization-related process that has not gone to substantial completion, such as a polymerization of monomers, cross-linking reaction, evaporation of solvents, and the like. For example, UV radiation may be used to cure a polymer after a desired particle concentration profile is obtained. The polymer may be a photopolymer. The polymer may be a copolymer, and in some embodiments may have additional components, for example to facilitate processing. In some embodiments, a voltage may be applied at the same time as curing the uncured polymer. In some embodiments, a migration rate of the nanoparticles may be controlled by controlling a viscosity of the polymer, controlling a value of the applied voltage, controlling a value of a charge on the charged nanoparticles, controlling a curing rate of an uncured polymer, or a combination thereof. A refractive index profile of the nanoparticle composite may be controlled using the nanoparticles dispersed along the concentration gradient, for example by controlling a quantity (such as a total number, or weight) of the charged nanoparticles used to dope the polymer, controlling a refractive index of the charged nanoparticles, or a combination thereof. In some embodiments, a polymer may be doped with droplets having an electric charge. Applying the voltage may the charged droplets to migrate, thereby dispersing the droplets along a concentration gradient related to a distance from the die.

In some embodiments, a method of making a light emitting diode (LED) comprises: doping a polymer with droplets, wherein the droplets have a droplet refractive index, and the droplets have an electric charge; at least partially encapsulating a die in the polymer; and applying a voltage to the die, such that the droplets migrate, thereby dispersing the droplets along a concentration gradient related to a distance from the die.

In some embodiments, a gradient refractive index (GRIN) semiconductor diode comprises: a die at least partially encapsulated within a polymer, wherein nanoparticles having a nanoparticle refractive index are dispersed within the polymer with a concentration gradient related to a distance from the die. The die may be a light emitting diode die, a photodetector diode die, or a laser diode die.

In some embodiments, a method of making a semiconductor diode comprises doping a polymer with charged nanoparticles having a selected refractive index; at least partially encapsulating a die in the doped polymer; and applying a voltage to the die such that the nanoparticles migrate, thereby dispersing the nanoparticles along a concentration gradient related to a distance from the die. The die may be a light emitting diode die, a photodetector diode die, or a laser diode die.

With respect to the use of substantially any plural and/or singular terms herein, those having skill in the art can translate from the plural to the singular and/or from the singular to volume of wastewater can be received in the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (for example, “ a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (for example, “ a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible sub-ranges and combinations of sub-ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into sub-ranges as discussed above. Finally, as will be understood by one skilled in the art, a range includes each individual member. Thus, for example, a group having 1-3 articles refers to groups having 1, 2, or 3 articles. Similarly, a group having 1-5 articles refers to groups having 1, 2, 3, 4, or 5 articles, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

1. A gradient refractive index (GRIN) light emitting diode (LED), comprising:
a die at least partially encapsulated within a polymer; and
nanoparticles dispersed within the polymer,
wherein the nanoparticles have a nanoparticle concentration having a continuous concentration gradient related to a distance from the die, the continuous concentration gradient extending from location at least proximate to the die towards an exterior surface of the polymer, and
the nanoparticles have a nanoparticle refractive index, the polymer has a polymer refractive index, and the nanoparticle refractive index is different from the polymer refractive index.

2. The LED of claim 1, wherein the nanoparticle concentration increases or decreases with increasing distance from the die.

3. The LED of claim 2, wherein the nanoparticle refractive index is greater than the polymer refractive index.

4. The LED of claim 3, wherein the nanoparticles comprise titania, zirconia, tellurium dioxide, silicon carbide, diamond, niobia, hafnium dioxide, yttrium oxide, tantalum oxide, antimony trioxide, gallium phosphide, gallium nitride, alumina, germanium dioxide, or a combination thereof.

5. The LED of claim 2, wherein the nanoparticle refractive index is less than the polymer refractive index

6. The LED of claim 5, wherein the nanoparticles comprise silica, gallium oxide, or a combination thereof

7. The LED of claim 1, wherein the nanoparticles have an average diameter of between 10 nm and 50 nm.

8. The LED of claim 1, wherein the nanoparticles and the die comprise the same material.

9. The LED of claim 1, wherein a transmission band of the nanoparticles comprises a range of wavelengths that encompasses at least a majority of wavelengths in an emission band of the die.

10. The LED of claim 1, wherein the polymer further comprises phosphor particles dispersed within the polymer.

11. The LED of claim 10, wherein the phosphor particles are dispersed along a concentration gradient related to a distance from the die.

12. The LED of claim 1, wherein the polymer further comprises a porosity gradient comprising droplets dispersed within the polymer along a concentration gradient related to a distance from the die.

13. A method of making a GRIN light emitting diode (LED), the method comprising:
doping a polymer with charged nanoparticles that have a refractive index that is different from a refractive index of the polymer;
at least partially encapsulating a die in the doped polymer; and
applying a voltage to the die that causes the charged nanoparticles to migrate, thereby dispersing the nanoparticles along a concentration gradient related to a distance from the die.

14. The method of claim 13, wherein applying the voltage causes the charged nanoparticles to migrate toward the die or away from the die.

15. The method of claim 13, wherein the voltage is no more than about 5 volts.

16. The method of claim 13, further comprising doping the polymer with phosphor particles.

17. The method of claim 16, wherein applying the voltage causes the phosphor particles to migrate, thereby dispersing the phosphor particles along a concentration gradient related to a distance from the die.

18. The method of claim 13, wherein the polymer is uncured, and the method further comprises curing the polymer before, during or after application of the voltage to the die.

19. The method of claim 13, further comprising controlling a migration rate of the charged nanoparticles by controlling a viscosity of the polymer, controlling a value of the applied voltage, controlling a value of the charge on the charged nanoparticles, controlling a curing rate of an uncured polymer, or a combination thereof

20. The method of claim 13, further comprising controlling a refractive index distribution of the charged nanoparticles dispersed along the concentration gradient by controlling a quantity of the charged nanoparticles used to dope the polymer, controlling a refractive index of the charged nanoparticles, or a combination thereof.

21. The method of claim 13, further comprising doping the polymer with droplets having an electric charge.

22. The method of claim 21, wherein applying the voltage causes the charged droplets to migrate, thereby dispersing the droplets along a concentration gradient related to a distance from the die.

23. A method of making a GRIN light emitting diode (LED), the method comprising:
doping a polymer with charged droplets, wherein the droplets comprise gas, plasma or liquid, and have a droplet refractive index that is different from the refractive index of the polymer;
at least partially encapsulating a die in the doped polymer; and
applying a voltage to the die that causes the charged droplets to migrate, thereby dispersing the droplets along a concentration gradient related to a distance from the die.

24. The LED of claim 1, wherein the nanoparticles are present in the polymer in at least about 1% volume fraction.
